(19) United States
(12) Patent Application Publication
(10) Pub. No.: US 2016/0225851 A1
(43) Pub. Date: Aug. 4, 2016

(54) SEMICONDUCTOR STRUCTURE AND METHOD FOR FORMING THE SAME

(71) Applicant: PEKING UNIVERSITY, Beijing (CN)

(72) Inventors: Ming LI, Beijing (CN); Yuancheng YANG, Beijing (CN); Jiewen FAN, Beijing (CN); Haoran XUAN, Beijing (CN); Hao ZHANG, Beijing (CN); Ru HUANG, Beijing (CN)

(21) Appl. No.: 15/026,325

(22) PCT Filed: Apr. 24, 2015
(86) PCT No.: PCT/CN2015/077399

§ 371 Date: Mar. 31, 2016

(30) Foreign Application Priority Data
Jun. 19, 2014 (CN) 201410275700.1

(51) Int. Cl. H01L 29/06; H01L 29/423; H01L 21/02; H01L 29/66; H01L 21/3105; H01L 21/027; H01L 29/78; H01L 29/04

(52) U.S. Cl. CPC H01L 29/0673; H01L 29/785; H01L 29/42392; H01L 29/045; H01L 29/66795; H01L 21/31055; H01L 21/0274; H01L 21/02271; H01L 21/02236

(57) ABSTRACT

Disclosed is a semiconductor structure, comprising: a semiconductor substrate and multilayer superfine silicon lines, wherein a profile shape of each of the multilayer superfine silicon lines is controlled dually by a crystal orientation of the substrate and an axial crystal orientation of the line. Also disclosed is a method of forming the same comprises: forming a fin-shaped silicon island (Fin) and a source-drain region on the two ends thereof via an etching process; preparing a corrosion shielding layer for silicon; and forming multilayer superfine silicon lines. The invention has the following advantages: the locations and the sectional shapes of the multilayer superfine silicon lines finally formed are uniform and controllable; the anisotropic corrosion for silicon stop automatically, the process window is large, and silicon lines with different diameters may be achieved from the same silicon wafer.

### CROSS-REFERENCE TO RELATED APPLICATION

This present application is a U.S. national phase application filed under 35 U.S.C. §371 of International Patent Application No. PCT/CN 2015/077399, entitled SEMICONDUCTOR STRUCTURE AND METHOD FOR FORMING SAME, filed on Apr. 24, 2015, which application claims the benefit of CN Application No. 201410275700.1 filed on Jun. 19, 2014, the disclosures of which are herein incorporated by reference in their entireties.

### FIELD OF THE INVENTION

The present invention belongs to a field of super-large scale integrated circuit manufacturing technologies and relates to multilayer superfine silicon lines structure and a method for preparing the same, and in particular, to a method for preparing location-shape-controllable multilayer superfine silicon lines by combining a fin-shaped silicon island sidewall mask technology and a silicon anisotropic corrosion technology.

### BACKGROUND OF THE INVENTION

As Moore law progresses to a 22 nm process node, traditional planar devices can no longer meet the requirement of Moore law, because the performance thereof degrades seriously due to the short channel effect and the reliability problem of the devices. A three-dimensional multi-gate device (Multi-gate MOSFET, MuGFET) taking a fin-shaped field effect transistor (FinFET) as representative realizes mass production successfully at the 22 nm node due to its outstanding capacity for inhibiting short channel effect and advantages such as high integration density and compatibility with traditional CMOS processes.

Among the three-dimensional multi-gate devices, Multi-Bridge-Channel Gate-all-around Nanowire FET (MBC GAA NWFET) becomes a strong competitor after progressing to 22 nm node due to its advantages such as outstanding gate control ability, ultra-high integration density and ultra-high drive current, etc.

One of the key technologies for manufacturing a Multi-Bridge-Channel Gate-all-around Nanowire FET is to prepare multilayer superfine silicon lines with location and sectional shape being uniform and controllable.

Ricky M. Y. Ng group from Hongkong Science and Technology University forms multilayer nanowires arranged from top to bottom by combining the Bosch process and sacrificial oxidization during Inductively Coupled Plasma (ICP) Etching [M. Y. Ng Ricky, et al., EDL, 2009, 30 (5) : 520˜522]. However, the location and sectional shape of the nanowire formed by this method are uncontrollable due to process fluctuation, thereby causing device performance serious fluctuation.

Sung-Young Lee, et al., from Samsung Electronics, Korea, successfully prepare a Multi-Bridge-Channel FET on a bulk silicon substrate by taking SiGe as a sacrificial layer [Sung-Young Lee, et al., TED, 2003, 2 (4): 253-257.]. The key technology thereof is to obtain a Si—SiGe superlattice structure by epitaxy on a bulk silicon and obtain a multilayer hanging channel by removing the SiGe sacrificial layer via wet corrosion. However, the quality and thickness of each layer of film in the superlattice structure are limited by factors such as lattice mismatch and stress release, etc., and the process is relatively complex.

Therefore, it is in urgent need for a structure of multilayer superfine silicon lines and a method for preparing the same, which not only has a high integration density but also can overcome the defects of the prior art.

### SUMMARY OF THE INVENTION

The invention provides a semiconductor structure and a method for forming the same, thereby improving the prior art technology.

Instruction for Terms: according to the definition in Chapter 1 of Semiconductor Physics written by Ye Liangxiu, (100), (110), (111) and (112) are Miller indices of a crystal face; <100>, <110>, <111> and <112> are crystal orientation indices.

The invention provides a semiconductor structure, which includes: a semiconductor substrate and multilayer superfine silicon lines, wherein, a profile shape of each of the multilayer superfine silicon lines is controlled dually by a crystal orientation of the substrate and an axial crystal orientation of the lines:

for the multilayer superfine silicon lines along <110> on (100) substrate, a top-layer line has a section of a pentagon, which is enclosed by one (100) crystal face, two (110) crystal faces and two (111) crystal faces; and each of lower-layer lines has a section of a hexagon, which is enclosed by two (110) crystal faces and four (111) crystal faces;

for the multilayer superfine silicon lines along <110> on (110) substrate, a top-layer line has a section of a pentagon, which is enclosed by one (110) crystal face, two (100) crystal faces and two (111) crystal faces; and the section of each of lower-layer lines has a section of a hexagon, which is enclosed by two (100) crystal faces and four (111) crystal faces;

for the multilayer superfine silicon lines along <110> on (111) substrate, each of the lines has a section of a rectangle, which is enclosed by two (111) crystal faces and two (112) crystal faces.

At the same time, the invention provides a method for forming a semiconductor structure, comprising:

A) providing a semiconductor substrate;

B) forming a fin-shaped silicon island (Fin);

In order to ensure that the anisotropic corrosion for the sidewall of the Fin can stop automatically on (111) crystal face so as to form the hanging multilayer superfine silicon lines with a polygonal section, the crystal orientation of the substrate, the length direction of the Fin and the crystal orientation of the sidewall should meet the following conditions: for (100) substrate, the length direction of the Fin and the crystal orientation of the sidewall thereof are both along <110>; for (110) substrate, the length direction of the Fin is along <110>, and the crystal orientation of the sidewall thereof is along <100>; and for (111) substrate, the length direction of the Fin is along <110>, and the crystal orientation of the sidewall thereof is along <112>;

An aspect ratio of the Fin should be selected to meet the requirement for a number of the layers of the fine lines finally formed;

C) forming a sidewall corrosion shielding layer of the Fin (sidewall mask technology);

The number and locations of the corrosion shielding layers define the number and locations of the layers of the fine lines; a layer-to-layer distance of the layers of the fine lines is defined by the thickness of the sacrificial layer, and in order to ensure that the multilayer superfine silicon lines formed after step D1 are completely separated upper and lower, the thickness (H) of the sacrificial layer and the width (W_{Fin}) of the Fin should meet the following conditions: for (100) substrate, H>W_{Fin}*tan 54.7°; for (110) substrate, H>W_{Fin}*cot 54.7°; for (111) substrate, H>0; wherein, 54.7° is an included angle between the (100) crystal face and the (111) crystal face of silicon;

It specifically comprises the steps of:

C1) preparing a sacrificial layer, including:
C101) depositing a sacrificial layer material on a silicon substrate, wherein a thickness of the deposited sacrificial layer material is greater than a height of the Fin;
C102) removing the sacrificial layer material on a top of the Fin via chemical-mechanical polishing (CMP) to expose the top of the Fin;
C103) defining a thickness of the sacrificial layer via etching;

C2) preparing the corrosion shielding layer, including:
C201) depositing a corrosion shielding layer material on the sacrificial layer, wherein a thickness of the deposited corrosion shielding layer material is greater than the height of the Fin;
C202) removing the corrosion shielding layer material on the top of the Fin via CMP to expose the top of the Fin;
C203) defining the thickness of the corrosion shielding layer via etching;

C3) repeating the steps C1, C2 alternately, and forming a stacked structure of cyclic “sacrificial layer-corrosion shielding layer” on the sidewall of the Fin;

C4) depositing a corrosion shielding layer on top of the Fin;

C5) defining a wet corrosion window for silicon on the stacked structure of cyclic “sacrificial layer-corrosion shielding layer” via photolithography;

C6) transferring a pattern defined by photolithography to the stacked structure of “sacrificial layer-corrosion shielding layer” via an anisotropic etching process to expose the silicon substrate;

C7) removing the sacrificial layer;

D) forming multilayer superfine silicon lines by performing anisotropic corrosion to the Fin from the sidewall thereof, wherein under the protection of the sidewall corrosion shielding layer, the corrosion finally stops automatically on (111) crystal face to form the multilayer superfine silicon lines with a polygonal section, which specifically includes the steps of:

D1) forming the multilayer superfine silicon lines with the polygonal section via anisotropic corrosion; and

D2) removing the corrosion shielding layer from the multilayer superfine silicon lines.

Further, in step D2, after the removing of the corrosion shielding layer, performing sacrificial oxidization so that the sections of the multilayer superfine silicon lines may be changed to be circular and the radius thereof may be further reduced; the sacrificial oxidization is dry oxidization, and the temperature is 850-950° C., and preferably 925° C.;

Further, a source-drain region or an STI region in micrometer scale that is connected with the two ends of the Fin formed by step B may ensure that there is enough silicon as a support for the two ends of the multilayer superfine silicon lines formed by step D1;

Further, the depositing performed in step C1, C2 and C4 may be selected from Atomic Layer Deposition (ALD), Low Pressure Chemical Vapor Deposition (LPCVD), Plasma Enhanced Chemical Vapor Deposition (PECVD), Inductively Coupled Plasma Enhance Chemical Vapor Deposition (ICPECVD) or sputtering, etc.,.

Further, SiO₂ may be selected as the sacrificial layer material, and a BHF solution is employed for the release of the SiO₂ sacrificial layer, wherein the concentration of the BHF solution is HF:NH₄F=1:30˜1:100, and preferably 1:40, and the corrosion temperature is a room temperature; Si₃N₄ may be selected as the corrosion shielding layer material; concentrated phosphoric acid is employed for the removing of the Si₃N₄ corrosion shielding layer; and the corrosion temperature is 170° C.

Further, a combination of the sacrificial layer material and the corrosion shielding layer material is not limited to SiO₂ and Si₃N₄, but they should meet the following conditions: the etching speed ratio of the sacrificial layer to the photoresist is greater than 5:1; the etching speed ratio of the corrosion shielding layer to the photoresist is greater than 5:1; the etching speed ratio of the sacrificial layer to silicon is greater than 5:1; and the etching speed ratio of the corrosion shielding layer to silicon is greater than 5:1.

Further, a Tetramethyl Ammonium Hydroxide (TMAH) solution is employed for the anisotropic corrosion for the silicon; the concentration of the TMAH solution is 10˜25 wt %, and preferably, 25 wt %; a corrosion temperature is 35˜60° C., and preferably 40° C.

The invention further provides a Multi-Bridge-Channel Gate-all-around Nanowire FET, wherein the multilayer superfine silicon lines are prepared by the above method for forming a semiconductor structure, and then the Multi-Bridge-Channel Gate-all-around Nanowire FET may be formed by a standard CMOS process.

The invention has the following advantages and positive effects:

1) The locations and the sectional shapes of the multilayer superfine silicon lines finally formed are uniform and controllable;

2) The anisotropic corrosion for silicon stop automatically, the process window is large, and silicon lines with different diameters may be achieved from the same silicon wafer;

3) ICPECVD has a stronger narrow groove filling ability so that no cavity occurs when deposing the sacrificial layer material and the corrosion shielding layer material;

4) Lines with a size less than 10nm may be prepared in conjunction with the oxidization technology, meeting the key process requirements for small-size devices;

5) For the wet corrosion for polysilicon by a TMAH solution, the operation is simple, convenient and safe, and no metallic ion will be introduced, thus it is applicable for the integrated circuit manufacturing process; and

6) A method of processing from top to bottom is employed, which may be fully compatible with the bulk silicon planar transistor process, with a lower process cost.

### BRIEF DESCRIPTION OF THE DRAWINGS

FIGS. 1-14 are schematic flowcharts showing a process of preparing a structure of multilayer superfine silicon lines based on anisotropic corrosion according to the invention, and in each figure, (a) indicates a top view, and (b) and (c) indicate sectional views taken along A-A′ and B-B′ in (a) respectively, wherein:

FIG. 1 shows that a fin-shaped silicon island structure and a source-drain region connected therewith are formed by anisotropic etching;

FIG. 2 shows that a sacrificial layer is deposited, and a top of the Fin is exposed via CMP;

FIG. 3 shows that a thickness of the sacrificial layer is defined by etching;

FIG. 4 shows that a corrosion shielding layer for silicon is deposited, and the top of the Fin is exposed via CMP;

FIG. 5 shows that a thickness of the corrosion shielding layer is defined by etching;

FIG. 6 shows that a second sacrificial layer is deposited and a thickness thereof is defined;

FIG. 7 shows that a top corrosion shielding layer is deposited and polished via CMP;

FIG. 8 shows that an anisotropic corrosion window for silicon is defined and etched;

FIG. 9 shows that the sacrificial layer is released;

FIG. 10˜FIG. 12 show that multilayer superfine silicon lines with a polygonal section are formed via anisotropic corrosion;

FIG. 13 shows that sacrificial oxidization is performed on the superfine lines, and an oxide layer enwrapping around the silicon lines is removed via wet corrosion to obtain finally multilayer superfine silicon lines with a circular section; and

FIG. 14 shows a legend.

### DETAILED DESCRIPTION OF THE EMBODIMENTS

The invention will be described in detail below with reference to the accompanying drawings and specific embodiments.

### Embodiment 1

A 2-bridge circular nanowire structure with a diameter of about 10 nm may be achieved according to the following steps of:

1) thermally growing SiO₂ of a thickness 50 Å, on a (111) bulk silicon substrate, as a stress buffer layer between a hard mask and the silicon substrate;

2) depositing Si₃N₄ of a thickness 100 Å as etch hard mask via LPCVD;

3) defining a pattern of a Fin and a source-drain region connected with two ends of the Fin on the hard mask via photolithography, wherein the Fin structure has a width of 20 nm and a length of 300 nm, with a length direction along <110> and sidewalls each having a crystal orientation <110>;

4) transferring the pattern to the hard mask via anisotropic etching to expose the silicon substrate;

5) transferring the pattern on the hard mask to the silicon substrate via anisotropic etching to form the Fin and the source-drain region connected with the two ends of the Fin, wherein the Fin structure has a height of 1000 Å, the width of 20 nm and the length of 300 nm, with the length direction along <110> and the sidewalls each having the crystal orientation <110>;

6) removing photoresist;

7) removing the etch hard mask of Si₃N₄ with hot (170° C.) concentrated phosphoric acid;

8) removing the stress buffer layer of SiO₂ with a BHF solution (HF:NH₄F=1:40), as shown in FIG. 1;

9) depositing SiO₂ of a thickness 1500 Å via ICPECVD;

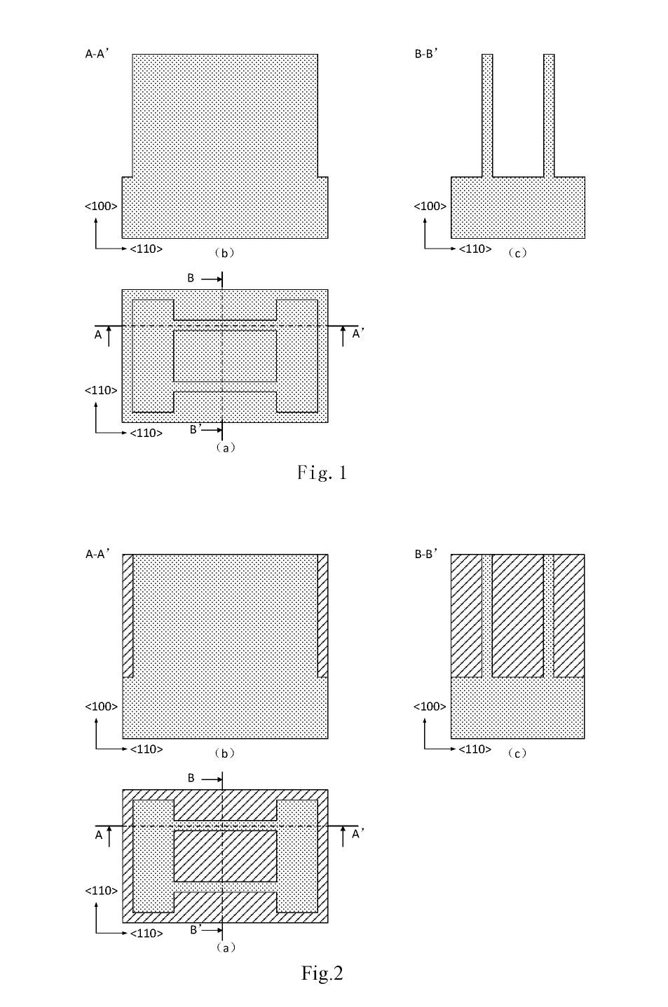

10) exposing the top of the Fin through Chemical Mechanical Polishing (CMP), as shown in FIG. 2;

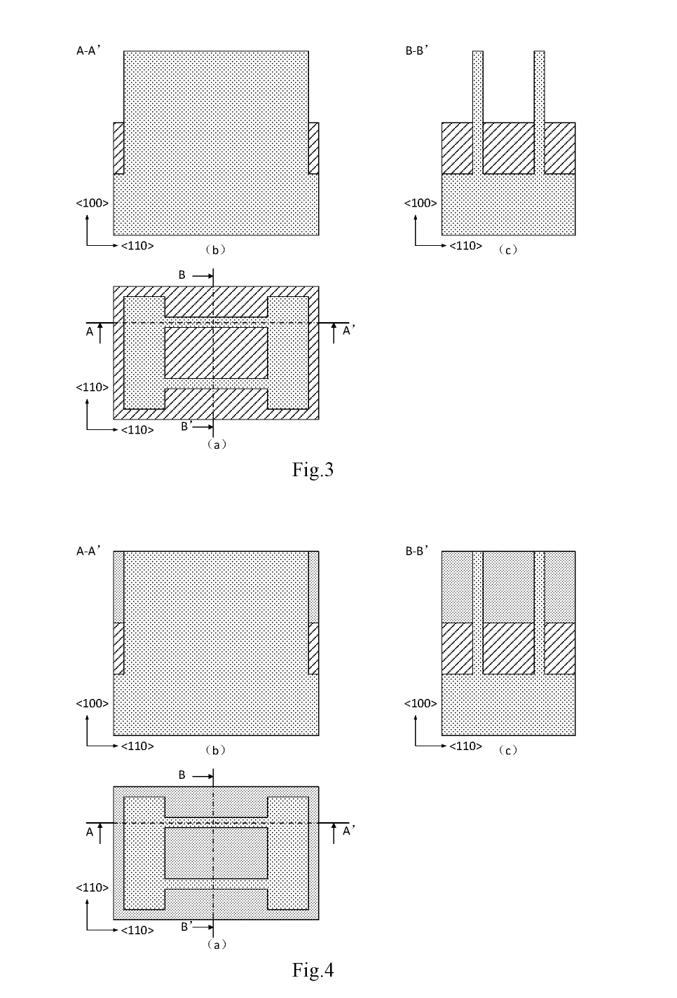

11) removing the SiO₂ of a thickness 700 Å via anisotropic etching, with the SiO₂ of a thickness 300 Å retained as a first sacrificial layer, as shown in FIG. 3;

12) depositing Si₃N₄ of a thickness 1200 Å via ICPECVD;

13) exposing the top of the Fin via CMP, as shown in FIG. 4;

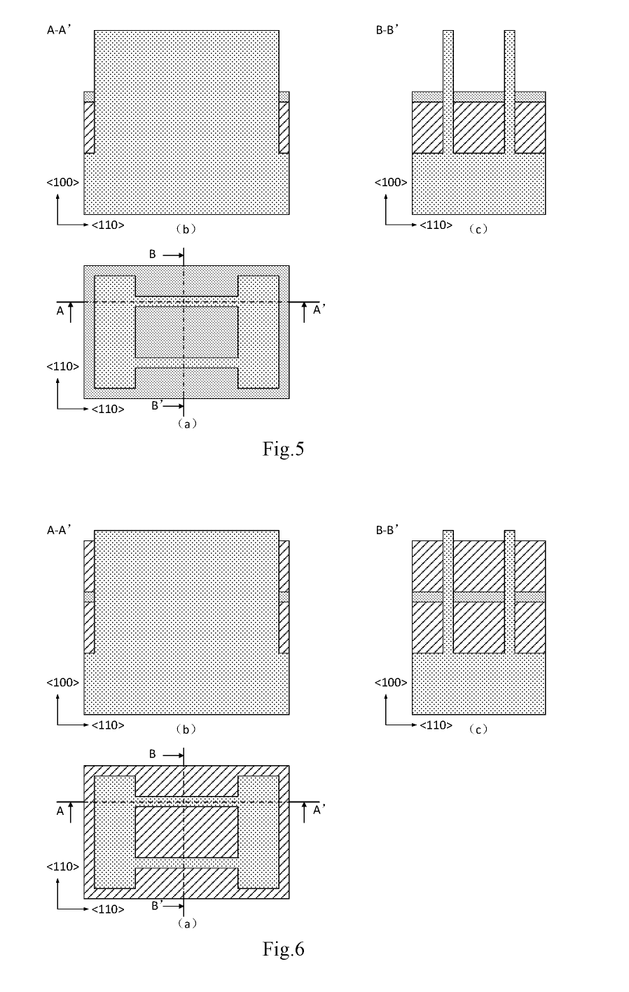

14) removing the Si₃N₄ of a thickness 500 Å via anisotropic etching, with the Si₃N₄of a thickness 200 Å retained as a first corrosion shielding layer for silicon, as shown in FIG. 5;

15) depositing SiO₂ of a thickness 1000 Å via ICPECVD;

16) exposing the top of the Fin via CMP;

17) removing the SiO₂ of a thickness 200 Å via anisotropic etching, with the SiO₂ of a thickness 50 Å 300 Å retained as a second sacrificial layer, as shown in FIG. 6;

18) depositing Si₃N₄ of a thickness 1500 Å via ICPECVD;

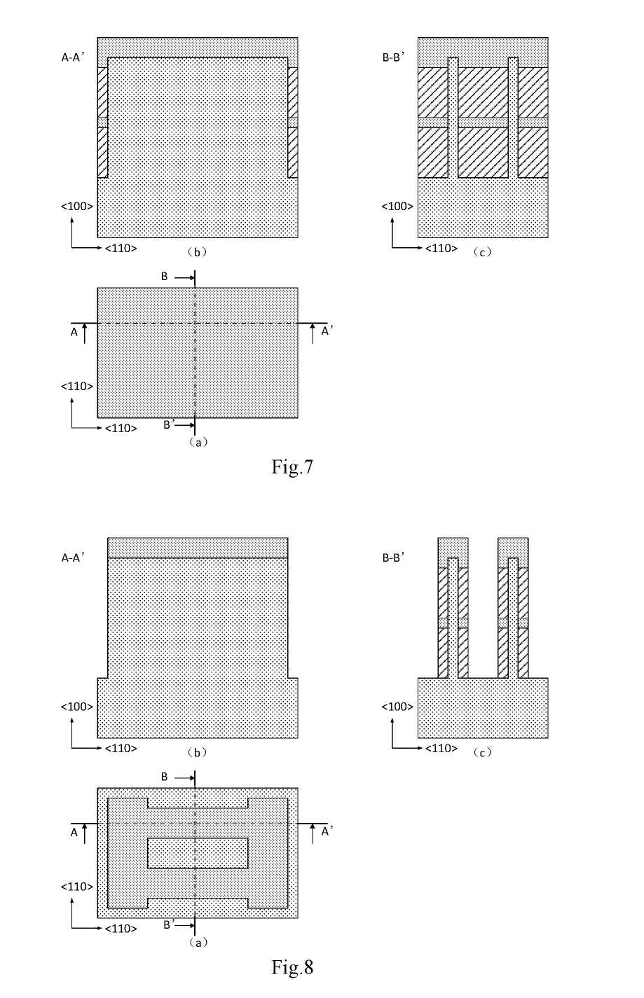

19) retaining the Si₃N₄ of a thickness 100 Å as a corrosion shielding layer for silicon on the top via CMP, as shown in FIG. 7;

20) defining a corrosion window for silicon via electron beam photolithography;

21) removing SiO₂—Si₃N₄ stacked materials in the window via anisotropic dry etching to expose the silicon on a bottom;

22) removing photoresist, as shown in FIG. 8;

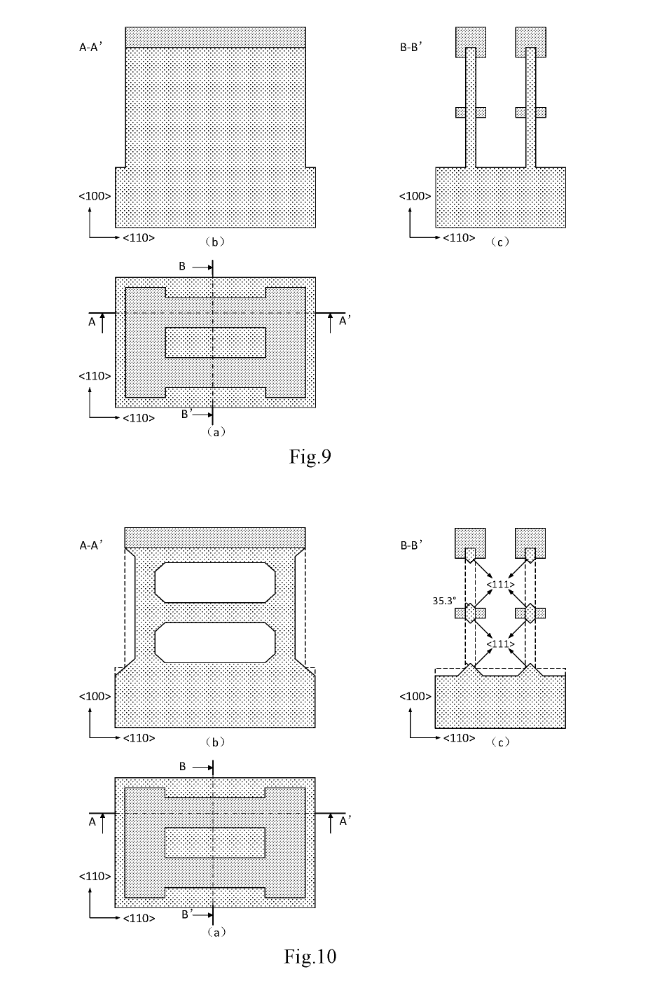

23) removing the sacrificial layer of SiO₂ via a BHF solution (HF:NH₄F=1:40), as shown in FIG. 9;

24) performing anisotropic corrosion on the silicon via a TMAH solution with a concentration of 25 wt % at 40° C. so as to completely separating a upper fine line and a lower fine line, as shown in FIG. 10;

25) removing the corrosion shielding layer of Si₃N₄ via hot (170° C.) concentrated phosphoric acid;

26) performing dry-oxygen oxidization at 925° C. to obtain a silicon nanowire with a circular section and a diameter of 5 nm;

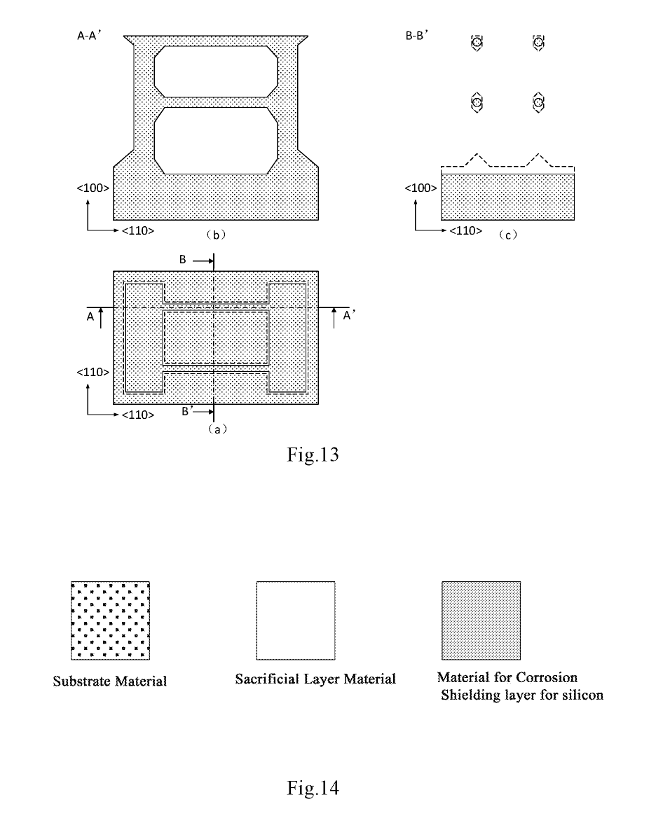

27) removing an oxide layer enwrapping around the silicon nanowire via a BHF solution (HF:NH₄F=1:40), as shown in FIG. 13;

Finally, the 2-bridge nanowire structure with a diameter of about 5 nm is obtained.

### Embodiment 2

A 2-bridge quadratic nanowire structure with a diameter of about 5 nm may be achieved according to the following steps of:

1) thermally growing SiO₂ of a thickness 50 Å, on a (100) bulk silicon substrate, as a stress buffer layer between a hard mask and the silicon substrate;

2) depositing Si₃N₄ of a thickness 100 < via LPCVD as etch hard mask;

3) defining a pattern of a Fin and a source-drain region connected with two ends of the Fin on the hard mask via photolithography, wherein the Fin structure has a width of 10 nm and a length of 300 nm, with a length direction along <110> and sidewalls each having a crystal orientation <112>;

4) transferring the pattern to the hard mask via anisotropic etching to expose the silicon substrate;

5) transferring the pattern on the hard mask to the silicon substrate via anisotropic etching to form the Fin and the source-drain region connected with the two ends of the Fin, wherein the Fin structure has a height of 1000 Å, the width of 10 nm and the length of 300 nm, with the length direction along <110> and the sidewalls each having the crystal orientation <112>;

6) removing photoresist;

7) removing the etch hard mask of Si₃N₄ with hot (170° C.) concentrated phosphoric acid;

8) removing the stress buffer layer of SiO₂ with a BHF solution (HF:NH₄F=1:40);

9) depositing SiO₂ of a thickness 1500 Å via ICPECVD;

10) exposing the top of the Fin through Chemical Mechanical Polishing (CMP);

11) removing the SiO₂ of a thickness 700 Å via anisotropic etching, with the SiO₂ of a thickness 300 Å retained as the first sacrificial layer;

12) depositing Si₃N₄ of a thickness 1200 Å via ICPECVD;

13) exposing the top of the Fin via CMP;

14) removing the Si₃N₄ of a thickness 500 Å via anisotropic etching, with the Si₃N₄ of a thickness 200 Å retained as the first corrosion shielding layer for silicon;

15) depositing SiO₂ of a thickness 1000 Å via ICPECVD;

16) exposing the top of the Fin via CMP;

17) removing the SiO₂ of a thickness 200 Å via anisotropic etching, with the SiO₂ of a thickness 300 Å retained as a second sacrificial layer;

18) depositing Si₃N₄ of a thickness 1500 Å via ICPECVD;

19) retaining the Si₃N₄ of a thickness 100 Å as a corrosion shielding layer for silicon on the top via CMP;

20) defining a corrosion window for silicon via electron beam photolithography;

21) removing SiO₂—Si₃N₄ stacked materials in the window via anisotropic dry etching to expose the silicon on a bottom;

22) removing photoresist;

23) removing the sacrificial layer of SiO₂ with a BHF solution (HF:NH₄F=1:40);

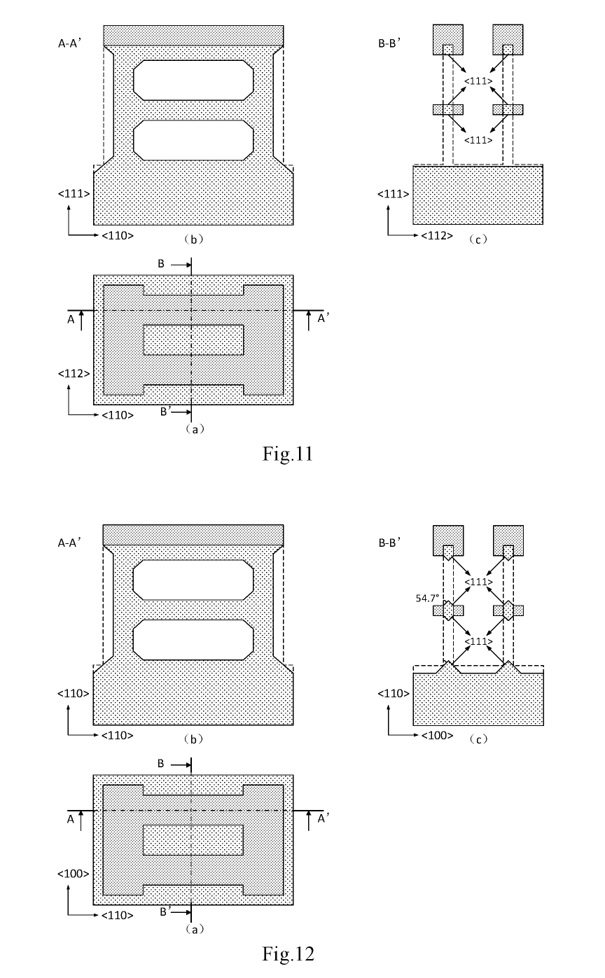

24) performing anisotropic corrosion on the silicon via a TMAH solution with a concentration of 25 wt % at 40° C. so as to completely separating a upper fine line and a lower fine line, as shown in FIG. 11;

25) removing the corrosion shielding layer of Si₃N₄ via hot (170° C.) concentrated phosphoric acid;

Finally, the 2-bridge nanowire structure with a quadratic section having a diameter of about 10 nm, is obtained.

### Embodiment 3

A 3-bridge nanowire structure with a diameter of about 10 nm is prepared.

1) thermally growing SiO₂ of a thickness 50 Å, on a (110) bulk silicon substrate, as a stress buffer layer between etch hard mask and the silicon substrate;

2) depositing Si₃N₄ of a thickness 100 Å via LPCVD as the etch hard mask for silicon;

3) defining a pattern of a Fin and a source-drain region connected with two ends of the Fin via photolithography, wherein the Fin structure has a width of 30 nm and a length of 300 nm, with a length direction along <110> and a sidewall having a crystal orientation <100>;

4) transferring the pattern to the hard mask via anisotropic etching to expose the silicon substrate;

5) transferring the pattern on the hard mask to the silicon substrate via anisotropic etching to form the Fin and the source-drain region connected with the two ends of the Fin, wherein the Fin structure has a height of 2100 Å, the width of 30 nm and the length of 300 nm, with the length direction along <110> and the sidewall having the crystal orientation <100>;

6) removing photoresist;

7) removing the etch hard mask of Si₃N₄ with hot (170° C.) concentrated phosphoric acid;

8) removing the stress buffer layer of SiO₂ with a BHF solution (HF:NH₄F=1:40);

9) depositing polycrystalline germanium of a thickness 2500 Å via ICPECVD;

10) exposing the top of the Fin through Chemical Mechanical Polishing (CMP);

11) removing the polycrystalline germanium of a thickness 1600 Å via anisotropic etching, with the polycrystalline germanium of a thickness 500 Å retained as a first sacrificial layer;

12) depositing SiO₂ of a thickness 2000 Å via ICPECVD;

13) exposing the top of the Fin via CMP;

14) removing the SiO₂ of a thickness 1400 Å via anisotropic etching, with the SiO₂ of a thickness 200 Å retained as a first corrosion shielding layer for silicon;

15) depositing polycrystalline germanium of a thickness 1800 Å via ICPECVD;

16) exposing the top of the Fin via CMP;

17) removing the polycrystalline germanium of a thickness 900 Å via anisotropic etching, with the polycrystalline germanium of a thickness 500 Å retained as a second sacrificial layer;

18) depositing SiO₂ of a thickness 1300 Å via ICPECVD;

19) exposing the top of the Fin via CMP;

20) removing the 700 A SiO₂ via anisotropic etching, retaining 200 Å SiO₂ as a corrosion shielding layer for the second layer of silicon;

21) depositing polycrystalline germanium of a thickness 1100 Å via ICPECVD;

22) exposing the top of the Fin via CMP;

23) removing the polycrystalline germanium of a thickness 200 Å via anisotropic etching, with the polycrystalline germanium of a thickness 500 Å retained as a third sacrificial layer;

24) depositing SiO₂ of a thickness 1500 Å via ICPECVD;

25) retaining the SiO₂ of a thickness 1000 Å via CMP as a corrosion shielding layer for silicon on the top;

26) defining a corrosion window for silicon via 193 nm immersed photolithography;

27) removing the polycrystalline germanium- SiO₂ stacked materials in the window via anisotropic dry etching to expose the silicon on a bottom;

28) removing photoresist;

29) removing the sacrificial layer of germanium via a mixed solution of aqua ammonia and hydrogen peroxide (NH₄OH:H₂O₂H₂O=2:2:5) at room temperature;

30) performing anisotropic corrosion on the silicon via a TMAH solution with a concentration of 25 wt % at 40° C. so as to completely separating a upper and a lower fine lines, as shown in FIG. 12;

31) removing the corrosion shielding layer of SiO₂ via a BHF solution (HF:NH₄F=1:40);

32) performing dry-oxygen oxidization at 925° C. to obtain a silicon nanowire with a circular section and a diameter of 5 nm;

33) removing an oxide layer enwrapping around the silicon nanowire via a BHF solution (HF:NH₄F=1:40);

Finally, the 3-bridge nanowire structure with a diameter of about 10 nm is obtained.

The embodiments of the invention are not used to limit the invention. Various possible variations and modifications or equivalent substitutions may be made to the technical solutions of the invention based on the above disclosed method and technology by any one skilled in the art without departing from the scope of the technical solutions of the invention. Therefore, any simple changes, equivalent variations and modifications to the above embodiments based on the technical essence of the invention, without departing from the technical solutions of the invention, all fall into the protection scope of the invention.

1. A semiconductor structure, comprising: a semiconductor substrate and multilayer superfine silicon lines, wherein, a profile shape of each of the multilayer superfine silicon lines is controlled dually by a crystal orientation of the substrate and an axial crystal orientation of the line;
for the multilayer superfine silicon lines along <110> on (100) substrate, a top-layer line has a section of a pentagon, which is enclosed by one (100) crystal face, two (110) crystal faces and two (111) crystal faces; and each of lower-layer lines has a section of a hexagon, which is enclosed by two (110) crystal faces and four (111) crystal faces;
for the multilayer superfine silicon lines along <110> on (110) substrate, the line on a top layer has a section of a pentagon, which is enclosed by one (110) crystal face, two (100) crystal faces and two (111) crystal faces; and each of the lines on the lower layers is a hexagon, which is enclosed by two (100) crystal faces and four (111) crystal faces; and
for the multilayer superfine silicon lines along <110> on (111) substrate, each of the lines has a section of a rectangle, which is enclosed by two (111) crystal faces and two (112) crystal faces.

2. A method for forming a semiconductor structure, comprising steps of:
A) providing a semiconductor substrate;
B) forming a fin-shaped silicon island (Fin); wherein, the following conditions should be met: for (100) substrate, the length direction of the Fin and the crystal orientation of the sidewall thereof are both along <110>; for (110) substrate, the length direction of the Fin is along <110>, and the crystal orientation of the sidewall thereof is along <100>; for (111) substrate, the length direction of the Fin is along <110>, and the crystal orientation of the sidewall thereof is along <112>; an aspect ratio of the Fin should be selected to meet the requirement for a number of the layers of the fine lines finally formed;
C) forming a sidewall corrosion shielding layer of the Fin, which specifically comprises steps of:
C1) preparing a sacrificial layer, comprising:
C101) depositing a sacrificial layer material on the substrate of silicon, wherein the deposited sacrificial layer material has a thickness greater than a height of the Fin;
C102) removing the sacrificial layer material on a top of the Fin via Chemical Mechanical Polishing (CMP) to expose the top of the Fin; and
C103) defining a thickness of the sacrificial layer via etching;
C2) preparing the corrosion shielding layer, comprising:
C201) depositing a corrosion shielding layer material on the sacrificial layer, wherein the deposited corrosion shielding layer material has a thickness greater than the height of the Fin;
C202) removing the corrosion shielding layer material on the top of the Fin via CMP to expose the top of the Fin;
C203) defining a thickness of the corrosion shielding layer via etching;
C3) repeating the steps C1, C2 alternately, and forming a stacked structure of cyclic “sacrificial layer-corrosion shielding layer” on the sidewall of the Fin;
C4) depositing a corrosion shielding layer on the top of the Fin;
C5) defining a wet corrosion window for silicon on the stacked structure of cyclic “sacrificial layer-corrosion shielding layer” via photolithography;
C6) transferring a pattern defined by photolithography to the stacked structure of the sacrificial layer-corrosion shielding layer via an anisotropic etching process to expose the substrate of silicon;
C7) removing the sacrificial layer;
D) forming multilayer superfine silicon lines by performing anisotropic corrosion to the Fin from the sidewall thereof, wherein under the protection of the sidewall corrosion shielding layer, the corrosion finally stops automatically on (111) crystal face to form the multilayer superfine silicon lines with a polygonal section, comprising steps of:
D1) forming the multilayer superfine silicon lines with the polygonal section via anisotropic corrosion;
D2) removing the corrosion shielding layer from the multilayer superfine silicon lines.

3. The method for forming a semiconductor structure according to claim 2, wherein, in step D2, after the removing of the corrosion shielding layer, performing sacrificial oxidization so that the sections of the multilayer superfine silicon lines are changed to be circular and the radius thereof is further reduced.

4. The method for forming a semiconductor structure according to claim 2, wherein, a source-drain region or an STI region connected with the two ends of the Fin formed by step B is in micrometer scale.

5. The method for forming a semiconductor structure according to claim 2, wherein, the depositing performed in step C1, C2 and C4 is selected from the group consisting of ALD, LPCVD, PECVD, ICPECVD and sputtering.

6. The method for forming a semiconductor structure according to claim 2, wherein, the sacrificial layer material is SiO2, a BHF solution is employed for the release of the sacrificial layer of SiO2, where the concentration of the BHF solution is HF:NH4F=1:30˜1:100, a corrosion temperature is a room temperature; Si3N4 is selected as the corrosion shielding layer material; concentrated phosphoric acid is employed for the removing of the corrosion shielding layer of Si3N4; and a corrosion temperature is 170° C.

7. The method for forming a semiconductor structure according to claim 2, wherein, a combination of the sacrificial layer material and the corrosion shielding layer material should meet the following conditions: an etching speed ratio of the sacrificial layer to a photoresist is greater than 5:1; an etching speed ratio of the corrosion shielding layer to the photoresist is greater than 5:1; an etching speed ratio of the sacrificial layer to silicon is greater than 5:1; and an etching speed ratio of the corrosion shielding layer to silicon is greater than 5:1.

8. The method for forming a semiconductor structure according to claim 2, wherein, a TMAH solution is employed for the anisotropic corrosion for the silicon, where the concentration of the TMAH solution is 10˜25 wt %, and a corrosion temperature is 35˜60° C.

9. The method for forming a semiconductor structure according to claim 2, wherein, in the step C, the number and locations of the corrosion shielding layers define the number and locations of the layers of the fine lines; a layer-to-layer distance of the layers of the fine lines is defined by the thickness of the sacrificial layer, and in order to ensure that the multilayer superfine silicon lines formed after step D1 are completely separated upper and lower, the thickness H of the sacrificial layer and the width WFin of the Fin should meet the following conditions: for (100) substrate, H>WFin * tan 54.7°; for (110) substrate, H>WFin*cot 54.7°; and for (111) substrate, H>0; wherein, 54.7° is an included angle between the (100) crystal face and the (111) crystal face of silicon.

10. The method for forming a semiconductor structure according to claim 3, wherein, the sacrificial oxidization is dry oxidization, and the temperature is 850˜950° C.

11. The method for forming a semiconductor structure according to claim 6, wherein, the concentration of the BHF solution is HF:NH4F=1:40.

12. A Multi-Bridge-Channel Gate-all-around Nanowire FET, wherein, the multilayer superfine silicon lines are prepared by the method for forming a semiconductor structure according to the method of claim 2, and then the Multi-Bridge-Channel Gate-all-around Nanowire FET is formed by a standard CMOS process.
